(19) United States
(12) Patent Application Publication
(10) Pub. No.: US 2015/0108539 A1
(43) Pub. Date: Apr. 23, 2015

(54) FABRICATION METHOD OF SEMICONDUCTOR DEVICE AND THE SEMICONDUCTOR DEVICE

(71) Applicant: FUJI ELECTRIC CO., LTD., Kawasaki-shi (JP)

(72) Inventor: Mitsuhiro KAKEFU, Matsumoto-city (JP)

(21) Appl. No.: 14/484,627

(22) Filed: Sep. 12, 2014

(30) Foreign Application Priority Data
Oct. 17, 2013 (JP) 2013-216007

(51) Int. Cl. H01L 21/02; H01L 29/73; H01L 29/66; H01L 21/38; H01L 21/266

(52) U.S. Cl. CPC H01L 21/02107; H01L 21/38; H01L 21/266; H01L 29/66325; H01L 29/73
USPC 257/139; 438/530

(57) ABSTRACT

A fabrication method of a semiconductor device includes forming a mask insulating film having a specified thickness on the top surface of an n-type semiconductor substrate, forming an opening at a specified position in the mask insulating film, carrying out ion implantation with p-type impurity ions onto the top surface, removing a layer portion formed in the mask insulating film with the p-type impurities included by the ion implantation, and carrying out heat treatment to diffuse the p-type impurities implanted into the n-type semiconductor substrate from the opening to a depth, thereby forming the p-type isolation region.

### CROSS-REFERENCE TO RELATED APPLICATION

This application claims priority from and the benefit of Japanese Application No. 2013-216007, filed Oct. 17, 2013, the entire disclosure of which is incorporated herein by reference.

### BACKGROUND OF INVENTION

1. Field of the Invention

Embodiments of the present invention relate to a fabrication method of a semiconductor device which method has a process for forming a deep impurity diffused layer accompanied by a high temperature and long time diffusion and to the semiconductor device. In particular, the invention relates to a reverse blocking Insulated Gate Bipolar Transistor (IGBT) used for an electric power converter.

2. Discussion of the Background

A reverse blocking IGBT 100, like an ordinary IGBT, is provided with a MOS structure 13 of a stacked structure as is shown in FIG. 2, a cross sectional view showing the principal part of a reverse blocking IGBT 100. The stacked structure of the MOS structure 13 is a structure including a gate electrode 13a formed on the top surface in an active region 14, arranged in the central section of an n-type semiconductor substrate 1, with a gate oxide film 13b provided in between. The n-type semiconductor substrate 1 has a collector electrode 17 on the bottom surface thereof with a p-type collector layer 16 provided in between. The outer periphery of the active region 14 is surrounded by a junction termination region 9, the outer periphery of which is further surrounded by a p-type isolation region 6 formed of a diffused layer particularly provided between both surfaces of the semiconductor substrate 1. The structure is a characteristic of a reverse blocking IGBT. By connecting the p-type isolation region 6 to the p-type collector layer 16, the junction termination of the p-type collector layer 16 is made to be exposed on the top surface side of the junction termination region 9 for enabling the junction termination to be protected by an insulating film. Hence, the reverse breakdown voltage of the IGBT is stabilized to make it possible to increase the voltage withstand reliability of the IGBT. When the breakdown voltage classes of the IGBT are 600V to 1200V, the thicknesses of the semiconductor substrates 1 are preferably made to be on the order of 50 μm to 200 μm, respectively, depending on breakdown voltages.

A technology is disclosed by which a mask insulating film and a field oxide film are removed after selective ion implantation with impurity ions to a semiconductor substrate. The removal is carried out for preventing out-diffusion of impurities introduced by ion implantation into the insulating film to be a mask and is therefore carried out prior to a heat treatment process for forming a deep impurity diffused layer (isolation region) by thermal diffusion. Moreover, a fabricating method is also disclosed by which a mask insulation film and a field oxide film are removed before forming a new oxide film to thereby prevent later-explained auto doping due to impurities (JP-A-5-62922).

Furthermore, a process is disclosed in which after implantation of impurity ions, only a layer with high concentrations of implanted phosphorus atoms and boron atoms is removed from a silicon oxide film that is used as a mask before carrying out thermal diffusion (JP-A-57-10262).

FIGS. 7A-E are cross-sectional views of the principal part of a semiconductor substrate showing related process steps of forming a p-type isolation region. An n-type FZ (Floating Zone) semiconductor substrate 20 is used which has a thickness of around 500 μm and an impurity concentration between 3×10¹³ cm⁻³ and 1.5×10¹⁴ cm⁻³. On the top surface of the n-type semiconductor substrate 20, an initial oxide film 21 having a thickness between 0.8 μm and 1.6 μm is formed (FIG. 7A). Thereafter, selective etching of the initial oxide film 21 is carried out to form an opening 22 at the section positioned on the outer periphery of the active region and the junction termination region, both of which will be formed on the semiconductor substrate 20 in the following process step (FIG. 7B). Then, boron ions with a dose of 5×10¹⁵ cm⁻² are implanted into the semiconductor substrate 20 from the opening 22 of the initial oxide film 21 as is indicated by arrows 22a to form an ion-implanted layer 22b (FIG. 7C). The initial oxide film 21 except the opening 22 is required to have a thickness with which most of the boron ions are made to stay in the initial oxide film 21 without penetrating the film 21 at ion implantation so that the film 21 functions as a mask for preventing the boron ions from being implanted into the semiconductor substrate 20. Hereinafter the initial oxide film 21 will be also referred to as a mask insulating film 21.

After this, with the mask insulating film 21 containing boron atoms being completely removed or completely left, the boron atoms in the ion implanted layer 22b are subjected to thermal diffusion to a depth between 50 μm and 200 μm in an oxygen atmosphere at 1300° C. to form the p-type isolation region 6 (FIG. 7D). In FIG. 7D, the case is shown in which the p-type isolation region 6 is formed with the initial oxide film 21 being completely left. For providing the diffused depth of the p-type isolation region 6 as being 50 μm, high temperature and long time heat treatment on the order at 1300° C. for 100 hours must be carried out and, for providing the diffused depth as being 200 μm, high temperature and long time heat treatment on the order at 1300° C. for 300 hours must be carried out. After the p-type isolation region 6 is formed, the mask insulating film 21 is removed from the whole surface of the semiconductor substrate 20 (FIG. 7E).

However, when the process step of removing the mask insulating film 21 from the whole surface of the semiconductor substrate 20 is carried out after the process step shown in FIG. 7C and the high temperature and long time heat treatment carried out for forming the p-type isolation region 6 explained with reference to FIG. 7D is carried out with the mask insulating film 21 being removed from the whole surface of the semiconductor substrate 20 unlike the process step shown in FIG. 7D, a phenomenon occurs in which boron atoms in the ion implanted layer 22b are effused from the top surface of the semiconductor substrate 20 during the high temperature and long time heat treatment to perform out-diffusion and are then introduced into the semiconductor substrate 20 to be diffused thereinto again. The phenomenon is known as “auto doping”. By the auto doping, an undesirable region into which boron atoms are introduced is formed on the surface of the semiconductor substrate 20. As a result, in a reverse blocking IGBT fabricated by a fabrication method, in which auto doping might occur in the fabrication process, a problem sometimes occurs which increases the forward breakdown voltage thereof to decrease the reverse breakdown voltage thereof and further to increase a reverse leak current. Thus, a measure was previously taken in practice which prevents a breakdown voltage from being lowered by keeping the specific resistance of a silicon substrate higher and keeping the substrate thicker beforehand with an amount corresponding to the lowered breakdown voltage estimated. However, a thickened substrate causes the on-state voltage of a device to increase to make a problem inevitable which worsens a tradeoff relation between an on-state voltage and a turn-off loss.

While, in a process in which a mask insulating film is completely left before carrying out high temperature and long time heat treatment, the out-diffusion of high concentration oxygen introduced into the semiconductor substrate 20 is inhibited by the mask insulating film 21. As a result, the oxygen concentration on the surface of the semiconductor substrate 20 becomes high to produce oxide deposits accompanying crystal defects, which results in a state of surface roughening. A gate oxide film formed on the surface of the semiconductor substrate with a roughened surface is to include many defects, which is liable to cause an inferior gate to cause a problem of an increase in inferior gates. The problem does not occur in the process of carrying out the high temperature and long time heat treatment after the mask insulating film is completely removed. Furthermore, in the case of the process of carrying out the high temperature and long time heat treatment with the mask insulating film completely left, a phenomenon also becomes a problem in which boron atoms implanted into the oxide film by ion implantation pass through the oxide film by the high temperature and long time heat treatment to diffuse into the semiconductor substrate.

### SUMMARY

Embodiments of the invention provide a fabrication method of a semiconductor device which method is capable of inhibiting the occurrence of auto doping with boron atoms or inhibiting boron atoms in a mask insulating film from diffusing into a semiconductor substrate to minimize occurrences of lowering in a reverse breakdown voltage and inferior gates and to provide the semiconductor device.

Embodiments of the invention also provide a fabrication method of a semiconductor device having an active region including a MOS gate structure and a junction termination region surrounding the active region on one principal surface of a first conduction type semiconductor substrate, having a second conduction type semiconductor layer on the other principal surface, and having a second conduction type isolation region at a specified position surrounding the active region and the junction termination region, the isolation region contacting the first conduction type semiconductor substrate from the one principal surface to the second conduction type semiconductor layer on the other principal surface. The method includes the first step of forming a mask insulating film having a specified thickness on the one principal surface of the first conduction type semiconductor substrate, the second step of forming an opening for forming the second conduction type isolation region at the specified position in the mask insulating film, the third step of carrying out ion implantation with second conduction type impurity ions onto the one principal surface of the first conduction type semiconductor substrate with a specified dose at a specified acceleration energy to implant the second conduction type impurity ions thereinto from the opening in the mask insulating film, the fourth step of removing a layer portion formed in the mask insulating film with the second conductivity type impurities included by the ion implantation, thereby thinning the mask insulating film, and the fifth step of carrying out heat treatment to diffuse the second conduction type impurities implanted into the first conduction type semiconductor substrate from the opening formed in the mask insulating film to a depth at which the second conduction type semiconductor layer is to be provided, thereby forming the second conduction type isolation region.

The thickness of the mask insulating film left after the mask insulating film is thinned in the fourth step may be between 300 nm and 400 nm. Moreover, the layer portion with a thickness equal to or more than a sum of the mean range of the second conduction type impurity ions ion-implanted into the mask insulating film and the six times the standard deviation of the mean range may be removed from the mask insulating film in the fourth step.

The second conduction type isolation region may be formed from the opening to a depth from 50 μm to 200 μm in the fifth step. The semiconductor device fabricated by the fabrication method is desirably a reverse blocking IGBT.

According to embodiments of the invention, it is possible to provide a fabrication method of a semiconductor device which method is capable of inhibiting the occurrence of auto doping with boron atoms or inhibiting boron atoms in a mask insulating film from diffusing into a semiconductor substrate to minimize occurrences of lowering in a reverse breakdown voltage and inferior gates and to provide the semiconductor device.

### BRIEF DESCRIPTION OF THE DRAWINGS

FIGS. 1A, 1B, 1C, 1D, and 1E are cross-sectional views of the principal part of a semiconductor substrate showing the process steps of forming a p-type isolation region in the fabrication method of a semiconductor device according to an embodiment of the invention.

FIG. 2 is a cross sectional view showing the principal part of a reverse blocking IGBT.

FIGS. 3A and 3B are views showing distributions of concentrations of boron atoms in the depth direction of the semiconductor substrate in a section other than the p-type isolation region after the p-type isolation region is formed, in which the distribution when the p-type isolation region is formed with the mask insulating film completely removed by the related method is shown in FIG. 3A and the distribution when the p-type isolation region is formed by the method according to the invention is shown in FIG. 3B.

FIG. 4 is a diagram showing a relationship between the reverse breakdown voltage and the thickness of a left film after a layer portion including ion-implanted boron atoms is removed by etching from the surface of the mask insulating film 21 in a reverse blocking IGBT with a breakdown voltage of 600V.

FIG. 5 is a diagram showing a relationship between the forward breakdown voltage and the thickness of a left film after a layer portion including ion-implanted boron atoms is removed by etching from the surface of the mask insulating film 21 in a reverse blocking IGBT with a breakdown voltage of 600V.

FIG. 6 is a diagram showing a relationship between the proportion of defective gates and the thickness of a left film after a layer portion including ion-implanted boron atoms is removed by etching from the surface of the mask insulating film 21 in a reverse blocking IGBT with a breakdown voltage of 600V.

FIGS. 7A, 7B, 7C, 7D, and 7E are cross-sectional views of the principal part of a semiconductor substrate showing related process steps of forming a p-type isolation region.

### DESCRIPTION OF THE ILLUSTRATED EMBODIMENTS

In the following, an example of the fabrication method of a semiconductor device according to exemplary embodiments of the invention will be explained in detail with reference to attached drawings.

In the specification and the attached drawings, a leading character “n” attached to the name of a layer or a region means that electrons are major carriers in the layer or the region and a leading character “p” attached to the name of a layer or a region means that holes are major carriers in the layer or the region. Moreover, a sign “+” attached to the leading character “n” or “p” means that the impurity concentration in the layer or the region is relatively higher and a sign “−” attached to the leading character “n” or “p” means that the impurity concentration in the layer or the region is relatively lower. Furthermore, in the explanation of the example and in the attached drawings, similar arrangements will be denoted with the same reference numerals and signs with redundant explanations thereof being omitted. In addition, the attached drawings with reference to which the example will be explained are drawn neither to an accurate scale nor with an accurate dimensional proportion for the purpose of making the drawn items easy to see and easy to understand. Further, the invention is not limited to the descriptions of the embodiments explained in the following.

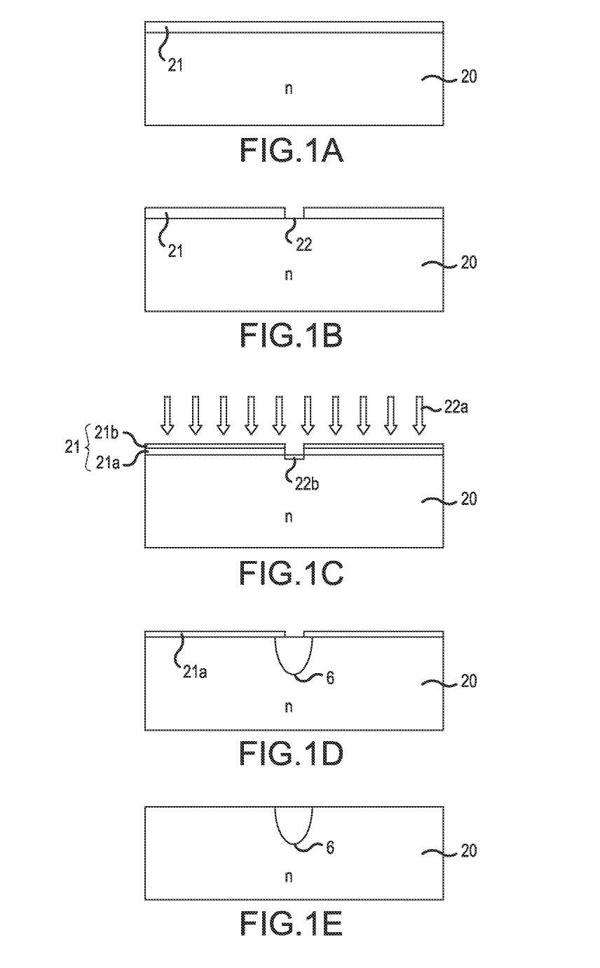

FIGS. 1A, 1B, 1C, 1D, and 1E are cross-sectional views of the principal part of a semiconductor substrate showing the process steps of forming a p-type isolation region 6 in the fabrication method of a semiconductor device according to an embodiment of the invention. An n-type FZ semiconductor substrate 20 is used which has a thickness of around 500 μm and an impurity concentration between 3×10¹³ cm⁻³ and 1.5×10¹⁴ cm⁻³. On the top surface of the n-type semiconductor substrate 20, an initial oxide film 21 having a thickness of between 0.8 μm and 1.6 μm is formed (FIG. 1A). Thereafter, selective etching of the initial oxide film 21 is carried out to form an opening 22 at the section positioned on the outer periphery of the active region and the junction termination region both of which will be formed on the semiconductor substrate 20 in the following process steps (FIG. 1B). The initial oxide film 21 in the process steps after the process step shown in FIG. 1B is also referred to as a mask insulating film 21. Then, boron ions with a dose of 5×10¹⁵ cm⁻² are implanted into the semiconductor substrate 20 from the opening 22 in the initial oxide film 21 as is indicated by arrows 22a to form an ion-implanted layer 22b (FIG. 1C).

The acceleration energy (keV) for the boron ion implantation is to be changed depending on the diffused depth of a p-type isolation region 6 that will be formed later. In a device with a breakdown voltage of 600V and a device with a breakdown voltage of 1200V, acceleration energies of 45 keV and 200 keV, respectively, may be used. By the ion implantation, the initial oxide film 21 except the opening 22 comes to be formed with an oxide film 21b and an oxide film 21a. The oxide film 21b has a thickness with which most of the boron ions are made to stay in the initial oxide film 21 without penetrating the film 21 at ion implantation so that the film 21 functions as a mask for preventing the boron ions from being implanted into the semiconductor substrate 20. The oxide film 21a has few ion-implanted boron atoms therein and may have a thickness of 300 nm or more. The mean range Rp of the implanted boron ions varies depending on the acceleration energy of ion implantation. Thus, the thickness of the oxide film 21b should be changed depending on the mean range Rp. The reason that the oxide film 21a, as the rest of the mask insulating film 21 from which the oxide film 21b is removed by etching, should have a thickness of 300 nm or more is that the oxide film 21a with the film thickness of less than 300 nm may cause a sudden increase in adverse effects due to defects such as pin holes and surface crystal defects to suddenly make the oxide film 21a lessen a masking effect against auto doping caused by the boron atoms in the ion implanted layer 22b.

In this embodiment, the oxide film 21 is provided with a thickness with which the oxide film 21a including no implanted boron atoms is left with a specified thickness beneath the oxide film 21b including implanted boron atoms after boron ion implantation rather than with a thickness only making the implanted boron ions not penetrate the mask insulating film 21, and the oxide film 21b including boron atoms is then removed by etching before carrying out thermal diffusion of implanted boron atoms to thereby leave only the oxide film 21a including no boron atoms with a specified thickness.

For example, when the acceleration energy of boron ions is 45 keV, the mean range Rp of the implanted boron ions is approximately 145 nm and the standard deviation σ of the mean range Rp is 45 nm. A mask insulating film 21 with the thickness of 800 nm (0.8 μm), even though that the range of the implanted boron ions has variations by six times the standard deviation (6σ) in addition to the mean range Rp is taken into consideration, may fulfill the requirement for the thickness of the oxide film 21b that substantially no implanted boron ions penetrate the mask insulating film 21 and the requirement for the thickness of the oxide film 21a that the thickness of the oxide film 21a including few boron atoms is equal to or more than 300 μm.

Moreover, when the acceleration energy of boron ions is 200 keV, the mean range Rp of the implanted boron ions is approximately 564 nm and the standard deviation σ of the mean range Rp is 95 nm. In this case, a mask insulating film 21 with the thickness of 1600 nm (1.6 μm), even though that the range of the implanted boron ions has variations by six times the standard deviation (6σ) in addition to the mean range Rp is taken into consideration like in the foregoing case, may fulfill the requirements for the thickness of the oxide film 21b and the thickness of the oxide film 21a.

After the process step shown in FIG. 1C, the section of the oxide film 21b is removed from the mask insulating film 21 by etching to thin the mask insulating film 21 to leave the oxide film 21a. Then, by long time processing in an oxygen atmosphere at 1300° C., the boron atoms in the ion implanted layer 22b are subjected to thermal diffusion to a depth between 50 μm and 200 μm to form the p-type isolation region 6 (FIG. 1D). For providing the diffused depth of the p-type isolation region 6 as being 50 μm, for example, heat treatment at 1300° C. for a time on the order of 100 hours may be carried out and, for providing the diffused depth as being 200 μm, heat treatment at 1300° C. for a time on the order of 300 hours may be carried out. In this way, in the example, high temperature and long time heat treatment is carried out with the oxide film 21a including few implanted boron atoms used as a mask. This prevents an undesirable p-type region including boron atoms from being formed in the semiconductor substrate 20 by auto doping with boron atoms or by boron atoms penetrating the oxide film 21a from the oxide film 21b including boron atoms.

FIGS. 3A and 3B are views showing distributions of concentrations of boron atoms in the depth direction of the semiconductor substrate 20 in a section other than the p-type isolation region 6 after the p-type isolation region 6 is formed, in which the distribution when the p-type isolation region 6 is formed with the mask insulating film 21 completely removed by the related method is shown in FIG. 3A and the distribution when the p-type isolation region 6 is formed by the method according to an embodiment of the invention is shown in FIG. 3B.

These are the results of investigations carried out with respect to the presence or the absence of any undesirable p-type region including boron atoms which region is formed by auto doping of boron atoms in a region in the semiconductor substrate 20 except the p-type isolation region 6. The investigations were carried out with respect to two cases, the case of forming the deep p-type isolation region 6 with the mask insulating film 21 completely removed by the related method and the case of forming the deep p-type isolation region 6 with the oxide film 21a, including no implanted boron atoms, being left after the oxide film 21b including implanted boron atoms is removed by etching by the method according to an embodiment of the invention.

The area where the undesirable p-type region is formed is also the area where MOS gate structures as main structures are to be formed on the top surface side of the IGBT. Hence, the formation of the undesirable p-type region prevents MOS structures from being normally formed to cause an increase in faulty characteristics. From FIG. 3A showing the boron concentration in the area where the undesirable p-type region is formed due to auto doping caused by completely removing the mask insulating film 21, it is known that boron concentrations equal to or more than 10¹⁵ cm⁻³ are detected down to the depth of approximately 0.2 μm from the top surface of the semiconductor substrate 20.

Furthermore, even inside the semiconductor substrate 20, boron concentrations range from 2×10¹⁴ cm⁻³ to 3×10¹⁴ cm⁻³ at some depths, which are higher than the impurity concentrations in the n-type semiconductor substrate 20 ranging from 3×10¹³ cm⁻³ to 1.5×10¹⁴ cm⁻³. Thus, there is a possibility that a p-type region is formed at the depth. Even when such a p-type region is not formed, impurity concentration of boron atoms is close to the impurity concentration of the n-type semiconductor substrate 20. Thus, p-type impurities and n-type impurities cancel with each other to sometimes lower the impurity concentration for the n-type semiconductor substrate 20. In FIG. 3B, there is shown the boron concentration in the case of forming the p-type isolation region 6 by the fabrication method according to an embodiment of the invention, in which the p-type isolation region 6 is formed with the oxide film 21a including no boron atoms left on the semiconductor substrate 20 by removing the oxide film 21b including implanted boron atoms from the mask insulating film 21. From FIG. 3B, it is known that the boron concentration is lowered to 10¹⁴ cm⁻³ or less except the top surface of the semiconductor substrate 20 to hardly form p-type regions. Moreover, inside the semiconductor substrate 20, most of the boron concentrations are below the detection limit to be lower than the impurity concentrations of the n-type semiconductor substrate 20 ranging from 3×10¹³ cm⁻³ to 1.5×10¹⁴ cm⁻³, from which it is known that the p-type region is hardly formed.

Below, the depth which implanted boron ions reach in the mask insulating film 21, the thickness of the oxide film 21b including the implanted boron atoms, and the thickness of the left oxide film 21a will be explained in detail with variation in the ranges of the boron ions explained in the foregoing taken into consideration.

Letting the mean value (middle value) of the ranges of boron ions exhibiting variations in the actual ranges thereof be the mean range Rp and the standard deviation σ thereof be ΔRp, the standard deviation ΔRp(σ), i.e. the variation in the range around the mean range Rp of 145 nm was 45 nm when the acceleration energy explained in the foregoing was 45 keV. In this case, it is considered that almost all of the implanted boron atoms are included within the distribution range of 6σ around the mean range Rp. The sum of the mean range Rp and 6σ becomes 415 nm (=145+6×45). Therefore, when the thickness of the mask insulating film 21 is 800 nm as was described in the foregoing and the acceleration energy of boron ions is 45 keV, by removing the 415 nm thick layer portion including boron atoms from the 800 nm thick mask insulating film 21 by means such as etching, few implanted boron atoms are to be included in the 385 nm thick left film of the oxide film 21a. In addition, in this case, the oxide film 21a left has the minimum thickness equal to or more than 300 nm.

Hence, when the thickness X of the mask insulating film 21 is obtained in reverse from the thickness of the oxide film 21b to be removed, the film thickness X is obtained as X≧300 nm+thickness of the oxide film 21b. Thus, since the thickness of the oxide film 21b including implanted ion atoms becomes 415 nm as was explained in the foregoing when the acceleration energy is 45 kev, the mask insulating film 21 with the thickness of at least 715 nm may be used. With error in thickness caused at etching taken into consideration, a thickness on the order of 800 nm may also be used.

In the same way, when the thickness of the mask insulating film 21 is 1600 nm as was described in the foregoing and the acceleration energy of boron ions is 200 keV, by removing the layer portion including boron atoms with a thickness of 1135 nm, a sum of the mean range Rp of 564 nm of the boron ions and six times the standard deviation ΔRp(σ) of 95 nm (6σ) of the mean range Rp, from the 1600 nm thick mask insulating film 21 by means such as etching, few implanted boron atoms are included in the 465 nm thick left film of the oxide film 21a.

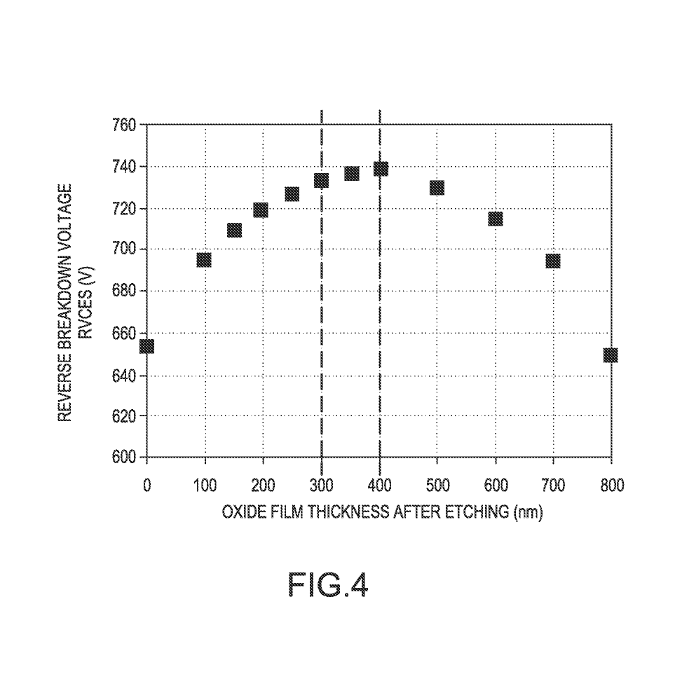

FIG. 4 is a diagram showing a relationship between the reverse breakdown voltage and the thickness of a left film after a layer portion including ion-implanted boron atoms is removed by etching from the surface of the mask insulating film 21 in a reverse blocking IGBT with a breakdown voltage of 600V according to an embodiment of the invention.

From FIG. 4, it is known that when the mask insulating film 21 has a thickness of 800 nm as the thickness of the as-formed initial oxide film, the reverse breakdown voltage is on the order of 600V, that with an increase in the thickness of the layer portion removed by etching from the surface of the mask insulating film 21, the reverse breakdown voltage increases, that when the thickness of the layer portion removed by etching becomes on the order of 400 nm and the thickness of the left film becomes on the order of 400 nm, the reverse breakdown voltage becomes the highest voltage of 740V, and that with a decrease in the thickness of the left film down to the order of 400 nm or less by a further increase in the thickness of the layer portion removed by etching exceeding on the order of 400 nm, the reverse breakdown voltage also decreases.

With the method according to an embodiment of the invention, in the case of the IGBT with the breakdown voltage of 600V, the thickness of the left film before the high temperature and long time heat treatment for boron atoms may be in a range of 300 nm to 400 nm. This is because the thickness equal to or more than 300 nm is a thickness being effective in inhibiting auto doping and because the thickness equal to or less than 400 nm is a thickness of a left film after removing from the initial oxide film 21 with the thickness of 800 nm a layer portion with a thickness on the order equal to or more than 415 nm, i.e. a thickness of 400 nm or more, as a sum of the mean range Rp of boron ions implanted into the mask insulating film 21 and six times the standard deviation σ thereof (6σ) as is explained in the foregoing. From FIG. 4, it is known that the reverse breakdown voltage is from 730V to 740V in a reverse blocking IGBT with a reverse breakdown voltage of 600V having a left film with a thickness within a range from 300 nm to 400 nm.

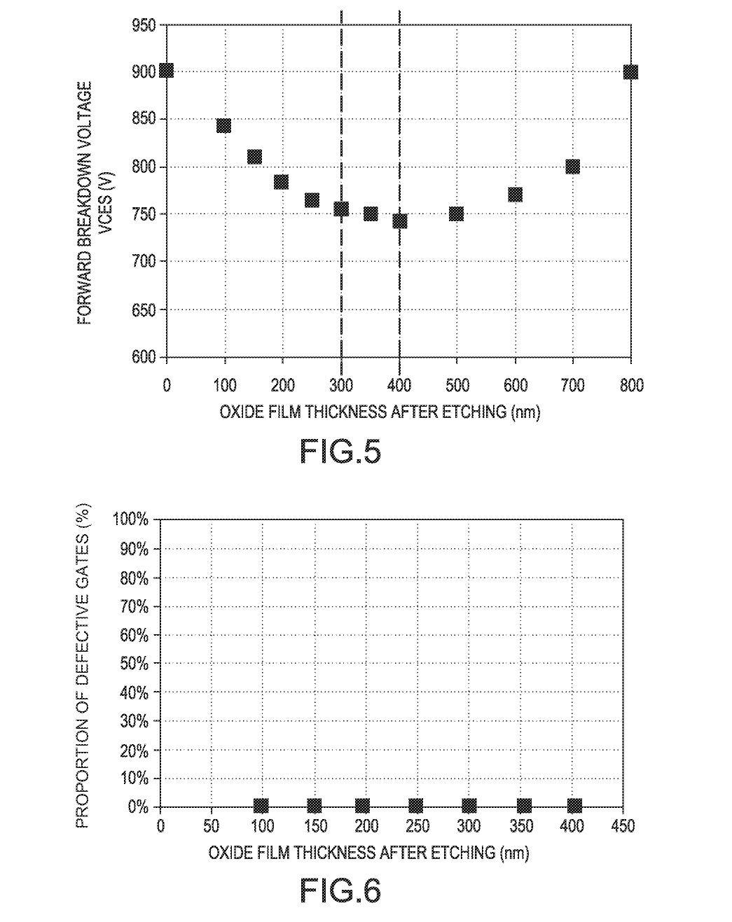

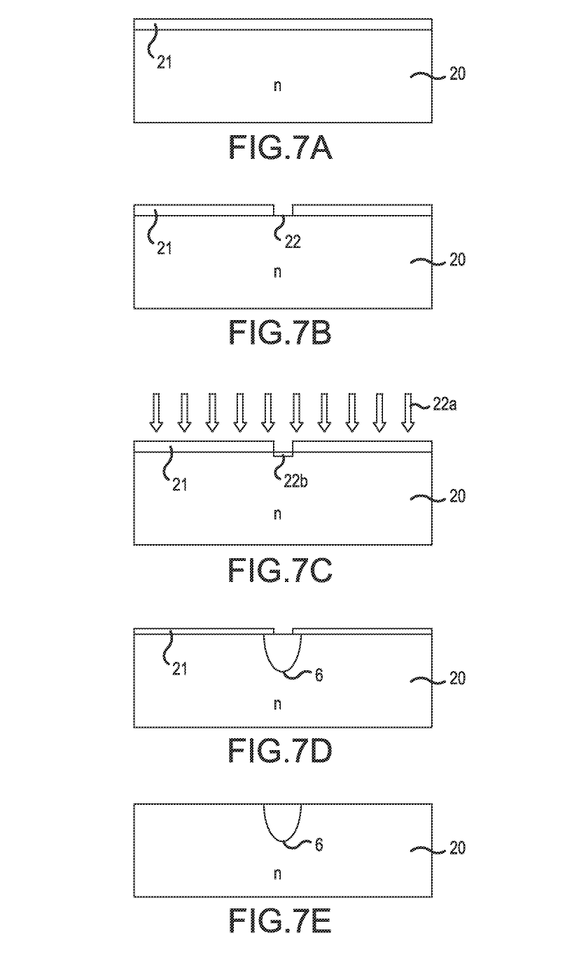

FIG. 5 is a diagram showing a relationship between the forward breakdown voltage and the thickness of a left film in the same range after a layer portion including ion-implanted boron atoms is removed by etching from the surface of the mask insulating film 21 in a reverse blocking IGBT with a breakdown voltage of 600V according to an embodiment of the invention. From FIG. 5, it is known that the forward breakdown voltage is from 740V to 760V in a reverse blocking IGBT with a forward breakdown voltage of 600V having a left film with a thickness within the same range from 300 nm to 400 nm.

The values of the mean ranges Rp of boron ions, standard deviations ΔRp(σ) thereof, Rp+4σ, Rp+5σ, Rp+6σ, initial oxide film thicknesses, maximum left film thicknesses and minimum left film thicknesses obtained with respect to the boron ion acceleration energies 45 keV and 200 keV described in the foregoing explanations and 100 keV not described therein are summarized in the following Table 1.

TABLE 1

| Boron ion range | Boron ion acceleration energy | | |
|---|---|---|---|
| in oxide film | 45 keV | 100 keV | 200 keV |
| Rp | 145 (nm) | 310 (nm) | 564 (nm) |
| ΔRp (σ) | 45 | 71 | 95 |
| Rp + 4σ | 325 | 594 | 945 |
| Rp + 5σ | 370 | 665 | 1039 |
| Rp + 6σ | 415 | 736 | 1135 |
| Oxide film thickness | | | |
| Initial oxide film thickness | 800 (nm) | 1200 (nm) | 1600 (nm) |
| Maximum left film thickness | 385 | 464 | 465 |
| Minimum left film thickness | 300 | 300 | 300 |

Subsequent to the process step shown in FIG. 1D, the whole oxide film 21a used as a mask for preventing auto doping may be removed by etching.

FIG. 6 is a diagram showing a relationship between the proportion of defective gates and the thickness of a left film after a layer portion including ion-implanted boron atoms is removed by etching from the surface of the mask insulating film 21 in a reverse blocking IGBT with a breakdown voltage of 600V according to an embodiment of the invention. From FIG. 6, it is known that the left film with a thickness between 100 nm and 400 nm substantially causes no defective gate because no crystal defect due to high concentration oxygen is formed on the surface of the substrate.

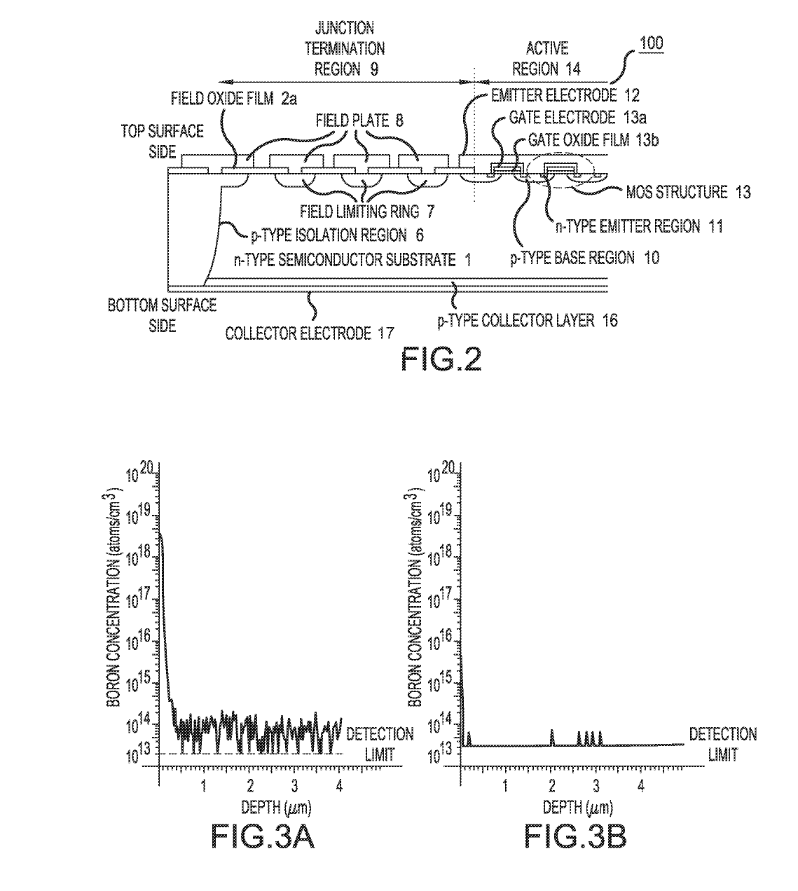

Subsequent to the process step shown in FIG. 1E, a field oxide film 2a shown in FIG. 2 is newly formed on the whole surface of the semiconductor substrate 20. Then, the known IGBT surface structure may be formed, which is made up of the active region 14, including the MOS structures 13, p-type base regions 10, n-type emitter regions 11 and an emitter electrode 12 etc., and the junction termination region 9, including field limiting rings 7 and field plates 8 etc. Subsequent to this, by carrying out irradiation with a beam such as an electron beam and heat treatment, the life time of minor carriers is adjusted so as to be a desired value. Next, the semiconductor substrate 20 is ground from the bottom surface to be thinned to a thickness suited for the breakdown voltage of the semiconductor device. The semiconductor substrate 20 thinned with the bottom surface thereof ground becomes the semiconductor substrate 1. Further, boron ion implantation is carried out on the bottom surface of the semiconductor substrate 1 to thereby form the p-type collector layer 16, the periphery of which is made to contact with the p-type isolation region 6. Then, the collector electrode 17 is formed which is in ohmic contact with the surface of the p-type isolation region 6. In this way, a reverse blocking IGBT is fabricated by the fabricating method of a semiconductor device according to an embodiment of the invention. The reverse blocking IGBT thus fabricated has the IGBT surface structure on the semiconductor substrate 1 surrounded by the p-type isolation region 6 with a high impurity concentration on the side surface and the p-type collector layer 16 on the bottom surface. Therefore, unlike an ordinary IGBT, no end of the reverse voltage withstand junction between the p-type collector layer 16 and the semiconductor substrate 1 is exposed on the side surface of the semiconductor substrate 1 without any protecting function. As a result, the reverse blocking IGBT according to an embodiment of the invention has no depletion layer exposed on the device side surface even when a reverse voltage is applied with the positive voltage onto the emitter side and the negative voltage onto the collector side, by which a stable reverse breakdown voltage characteristic can be obtained with high reliability.

According to the embodiment of the invention explained above, a fabrication method of a semiconductor device is provided as the method in which when a reverse blocking IGBT with a breakdown voltage of 600V is fabricated, the thickness of the mask insulating film is made to be 800 nm (0.8 μm), boron ion implantation is carried out at an acceleration energy of 45 keV before thinning the mask insulating film to a left film with a thickness of the order of 0.3 μm to 0.4 μm and thermal diffusion processing of boron atoms is then carried out to form a deep isolation region. According to the fabrication method in the example, the mask insulating film is thinned to the extent of substantially complete removal of the boron atoms in the mask insulating film. This makes it possible to enhance the out-diffusion of high concentration oxygen atoms entrapped in the vicinity of the substrate surface to bring the surface of the substrate into a sufficiently low oxygen concentration state. As a result, production of oxide deposits on the substrate surface (surface roughening) is inhibited to lessen the degree of the state of surface roughening on the substrate surface.

In addition, by removing only the oxide film including ion-implanted boron atoms by etching to leave the oxide film including few boron atoms, it is made possible to reliably inhibit boron atoms in the oxide film from penetrating the oxide film to diffuse into the semiconductor substrate in the subsequent high temperature and long time diffusion process and, along with this, to provide the left oxide film a masking effect against auto doping due to boron atoms effused from the substrate surface. For this purpose, the mask insulating film may be thinned by etching prior to the high temperature and long time diffusion process down to the depth greater than the sum of the mean range of the boron ions and six times the standard deviation of the mean range so that the maximum value of the thickness of the left film becomes 0.4 μm. Moreover, the reason that the minimum value of the thickness of the left film is determined to be 0.3 μm or more is that the oxide film thinner than the minimum value will cause the probability of producing pin holes and defects in the oxide film to be considerably high to lower the inhibiting effect of auto doping.

According to embodiments of the invention, proportion of defective gates can be held down to be equal to or less than 1% without lowering the breakdown voltage of the semiconductor device. Furthermore, boron atoms in an oxide film are inhibited from diffusing into a semiconductor substrate and, along with this, auto doping due to the boron atoms is inhibited to prevent a reverse breakdown voltage from being lowered, by which the specific resistance of an initial silicon substrate can be made to be low and further the thickness of the substrate can be made to be thin to lower an on-state voltage. Moreover, the isolation region becomes shallow by the amount of the substrate being thinned to shorten the time required for carrying out heat treatment for high temperature diffusion.

What is claimed is:

1. A fabrication method of a semiconductor device, the method comprising:
forming a mask insulating film on a first conduction type semiconductor substrate;
forming an opening in the mask insulating film;
implanting second conduction type impurity ions into the first conduction type semiconductor substrate via the opening in the mask insulating film;
removing a first portion of the mask insulating film having the implanted second conduction type impurity ions, such that a second portion of the mask insulating film remains on the first conduction type semiconductor substrate; and
heat treating the first conduction type semiconductor substrate, thereby forming a second conduction type isolation region.

2. The fabrication method of a semiconductor device as claimed in claim 1, wherein a thickness of the second portion of the mask insulating film is in a range of 300 nm to 400 nm.

3. The fabrication method of a semiconductor device as claimed in claim 1, wherein a thickness of the first portion of the mask insulating film is greater than or equal to a sum of the mean range of the second conduction type impurity ions ion-implanted into the mask insulating film and six times the standard deviation of the mean range.

4. The fabrication method of a semiconductor device as claimed in claim 1, wherein the second conduction type isolation region is formed to a depth of 50 μm to 200 μm in the first conduction type semiconductor substrate.

5. A semiconductor device fabricated by the fabrication method of claim 1, wherein the semiconductor device is a reverse blocking IGBT.

6. A fabrication method of a semiconductor device, the method comprising:
forming a mask insulating film on a first conduction type semiconductor substrate;
forming an opening in the mask insulating film;
implanting second conduction type impurity ions into the first conduction type semiconductor substrate via the opening in the mask insulating film;
removing a first portion of the mask insulating film having the implanted second conduction type impurity ions, such that a second portion of the mask insulating film remains on the first conduction type semiconductor substrate, the second portion of the mask insulating film having a trace amount or less of second conduction type impurity ions; and
heat treating the first conduction type semiconductor substrate, thereby forming a second conduction type isolation region.

7. The fabrication method of a semiconductor device as claimed in claim 6, wherein a thickness of the second portion of the mask insulating film is in a range of 300 nm to 400 nm.

8. The fabrication method of a semiconductor device as claimed in claim 6, wherein a thickness of the first portion of the mask insulating film is greater than or equal to a sum of the mean range of the second conduction type impurity ions ion-implanted into the mask insulating film and six times the standard deviation of the mean range.

9. The fabrication method of a semiconductor device as claimed in claim 6, further comprising removing the second portion of the mask insulating film after heat treating the first conduction type semiconductor substrate.
